(19) United States
(12) Patent Application Publication
(10) Pub. No.: US 2024/0377476 A1
(43) Pub. Date: Nov. 14, 2024

(54) POWER SUPPLY DEVICE

(71) Applicant: PHOENIX CONTACT GMBH & CO. KG, Blomberg (DE)

(72) Inventors: Nicola KESSLER, Bielefeld (DE); Hartmut HENKEL, Blomberg (DE); Jochen ZEUCH, Blomberg (DE); Stephan SAGEBIEL, Marienmuenster (DE)

(21) Appl. No.: 18/692,849

(22) PCT Filed: Sep. 19, 2022
(86) PCT No.: PCT/EP2022/075980

§ 371 Date: Mar. 18, 2024

(30) Foreign Application Priority Data
Sep. 21, 2021 (LU) 500675

(51) Int. Cl. G01R 31/42; G01R 19/165; G01R 19/25

(52) U.S. Cl. CPC G01R 31/42; G01R 19/16547; G01R 19/2509

(57) ABSTRACT

A power supply device for supplying at least one load from a three-phase supply network includes: a) a voltage converter with an input for connection to the three-phase supply network and an output for supplying the at least one load; b) a network analysis device for network analysis and generating at least one network parameter; and c) a message output. d) The network analysis device outputs the at least one network parameter at the message output. e) The at least one network parameter indicates a direction of rotation of the three-phase supply network at the input of the voltage converter.

### CROSS-REFERENCE TO PRIOR APPLICATIONS

This application is a U.S. National Phase application under 35 U.S.C. § 371 of International Application No. PCT/EP2022/075980, filed on Sep. 19, 2022, and claims benefit to Luxembourgian Patent Application No. LU 500675, filed on Sep. 21, 2021. The International Application was published in German on Mar. 30, 2023 as WO 2023/046636 Al under PCT Article 21 (2).

### FIELD

This disclosure relates to a power supply device for supplying at least one load from a supply network.

### BACKGROUND

From the prior art, power supply devices in the form of switching power supplies are known, which on the input side are fed from a supply network and on the output side supply at least one electrical load. In such a power supply device it is furthermore known to monitor the network quality of the input side supply network. What is of interest here for example are network parameters such as the harmonic content, the quality of the sinusoidal oscillation, phase and zero point shifts, the number and height of surge pulses, the direction of rotation or the insulation or grounding resistance. For measuring these network parameters separate network analysis devices are known, which are very complex and expensive. These are portable devices that are temporarily connected to the supply network and are able to detect and store network routes in a high temporal resolution over a certain period of time. However, this known type of network analysis is relatively expensive, as complex and correspondingly costly network analysis devices are required.

FIG. 1 shows a likewise known power supply device 1 according to the prior art, which on the input side is fed from a supply network via a plurality of input terminals 2-6. The supply network for example can be a three-phase network with an additional neutral conductor and a protective conductor. On the output side, the power supply device 1 feeds at least one load via two output terminals 7, 8. At the input of the power supply device 1 an AC voltage is applied, while at the output of the power supply device 1 a DC voltage is output. For conversion, a switching power supply 9 is arranged in the power supply device 1. In addition, the power supply device 1 also contains a signaling device 10 that can actuate a relay 11 in order to be able to output a binary signal at two signaling terminals 12, 13. Furthermore, the power supply device 1 contains a communication interface 14 via which the power supply device 1 can be controlled and queried. However, no network parameters can be output via the communication interface 14. What is also known, however, are such power supply devices 1 which can measure network parameters of the input-side supply network and can correspondingly actuate the relay 11. In this way, too, it is however not possible to output the network parameters themselves. Hence, the known power supply device 1 as shown in FIG. 1 neither provides for a satisfactory network analysis.

Further power supply units are described in WO 2010/102150 A1, US 2005/101193 A1 and US 2005/094336 A1. However, these are limited in their capabilities.

### SUMMARY

In an embodiment, the present invention provides a power supply device for supplying at least one load from a three-phase supply network, comprising: a) a voltage converter with an input for connection to the three-phase supply network and an output configured to supply the at least one load; b) a network analysis device for network analysis and configured to generate at least one network parameter; and c) a message output, d) wherein the network analysis device is configured to output the at least one network parameter at the message output, and e) wherein the at least one network parameter indicates a direction of rotation of the three-phase supply network at the input of the voltage converter.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 shows a schematic representation of a known power supply device according to the prior art;

FIG. 2 shows a schematic representation of a power supply device according to the solution; and

FIG. 3 shows a schematic representation of a system with the power supply device according to the solution.

### DETAILED DESCRIPTION

In an embodiment, the present invention improves the network analysis on a power supply device.

On the input side, the power supply device according to the solution is fed from a supply network. The supply network is an AC voltage network. The AC network is a three-phase AC network, wherein the supply network additionally can include a neutral conductor and/or a protective conductor.

On the output side, the power supply device according to the solution feeds at least one electrical load. It should be mentioned here that on the output side preferably a DC voltage is output. The solution is, however, not limited to direct current as regards the type of current emitted on the output side. Alternatively, it is also possible that an alternating current is output on the output side.

In accordance with the known prior art described above, the power supply device according to the solution also comprises a voltage converter with an input for connection to the supply network and an output for supplying the at least one load. The voltage converter for example can be a power pack, such as for example a switching power supply. As regards the type of the voltage converter, the solution hence is not limited to specific types of voltage converter.

In addition, the power supply device according to the solution in correspondence with the known power supply device described above includes an integrated network analysis device, which serves for network analysis and determines at least one network parameter that identifies the supply network applied on the input side or the output of the power supply device.

Furthermore, the power supply device according to the solution in correspondence with the known power supply device described above also contains a message output in order to be able to emit an output signal.

The solution provides that on the output side the network parameter determined by the integrated network analysis device is output at the message output. This provides for a simple network analysis by simply querying the network parameter from an external monitoring unit. Hence, for network analysis it no longer is required to temporarily connect a complex and correspondingly expensive network analysis device to the supply network in order to perform the network analysis. It is provided that the at least one network parameter comprises the direction of rotation of the three-phase supply network at the input of the voltage converter. The network analysis device hence is configured to determine the direction of rotation of the three-phase supply network by means of the network analysis. For example. when an electric motor is connected to the supply network, it can in this way be ensured that the motor is operated only in one specified direction of rotation. This is based on the knowledge that it can occur that a socket is connected incorrectly. In many loads, e.g. heaters or the like, such a fault typically goes unnoticed. In motors, however, such a fault can lead to a wrong direction of rotation and thereby to subsequent faults. With the described solution. this can be prevented by a simple check so that an improved network analysis can be achieved on a power supply device.

In one variant of the solution, the network analysis device integrated into the power supply device determines a further network parameter of the supply network at the input of the voltage converter. In accordance with the solution it is, however, also possible alternatively or additionally that the network analysis device integrated into the power supply device determines a further network parameter at the output of the power supply device. In addition, it is also possible in accordance with the solution that the integrated network analysis device performs the network analysis both on the input side and on the output side.

In a network analysis both at the input of the power supply device and at the output of the power supply device it is also possible in accordance with the solution that the quantities measured on the input side are linked with the quantities measured on the output side in order to determine the network parameter to be output. For example, it thus is possible to determine the efficiency of the power supply device or the losses in the power supply device as a network parameter. A network parameter of the at least one network parameter can also be a derived quantity, which is calculated from quantities measured on the input side and quantities measured on the output side.

Furthermore, it should be mentioned that the network analysis device integrated into the power supply device can measure current and/or voltage with a particular temporal resolution at particular time intervals, wherein corresponding measurement values of the current and/or the voltage are determined. For example, the time intervals can be less than 50 ms, 20 ms, 10 ms, 5 ms, 1 ms or 10 μs in order to provide for the desired high temporal resolution of the measurement. The network analysis device then can determine the network parameter from the measurement values determined in temporal succession. For example, statistical parameters can thus be calculated from the measurement values.

As regards the determined at least one network parameter, the solution is not limited to particular concrete network parameters. For example, the following network parameters can be determined in addition, wherein arbitrary combinations are also possible:
phase position of the supply network at the input of the voltage converter,
phase position at the output of the voltage converter,
voltages between the individual phases of the three-phase supply network at the input of the voltage converter (e.g. in combination with the phase position of the supply network at the input of the voltage converter).
voltages between the individual phases of the three-phase supply network and a neutral conductor at the input of the voltage converter,
insulation resistance of at least one phase of the supply network,
voltage type of the supply network for differentiating AC voltage and DC voltage,
frequency of the supply network.

In addition, the power supply device according to the solution can include a switching output in order to output a switching signal in dependence on the determined network parameter, wherein the switching signal optionally is binary and assumes either a switch-on state or a switch-off state. For example, an integrated relay can be actuated here corresponding to the switching signal.

Furthermore, the power supply device according to the solution can contain an optical indication in order to indicate the network parameter. For example, the optical indication can contain a light-emitting diode that for example can indicate a state of fault. In accordance with the solution it is, however, also possible that the optical indication contains a display (e.g. LCD display) on which the network parameter can be indicated.

Furthermore, the power supply device according to the solution also can include a communication interface in order to control the power supply device from outside and/or to output the network parameter or other data. The communication interface hence can selectively provide for a unidirectional data transmission or a bidirectional data transmission.

The voltage converter can be configured to provide a DC voltage of 24 V (or 12 V or 48 V) at its output. For example, a motor can be supplied therewith. In particular, this can be a safe DC voltage (SELV).

Finally, the solution also describes for a control cabinet with such a power supply device in the control cabinet.

Finally, the solution also describes a system with such a power supply device and/or such a control cabinet.

The system can comprise a motor connected or connectable to the supply network.

The motor can be adapted to start only when a predetermined direction of rotation is output at the message output and/or when a predetermined switching signal is applied at the switching output of the power supply device (e.g. a signal which indicates that the correct direction of rotation is applied, e.g. in the form of a binary signal).

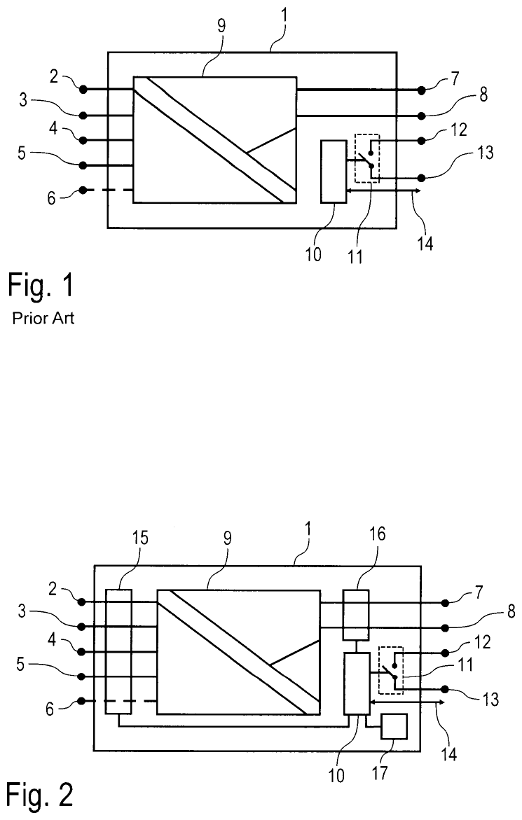

The known power supply device 1 as shown in FIG. 1 has already been explained above in the description of the prior art. FIG. 2 shows a preferred exemplary embodiment of a power supply device 1 according to the solution, which partly corresponds with the known power supply device 1 described above, which is shown in FIG. 1, so that reference is made to the above description of FIG. 1 in order to avoid repetitions, wherein the same reference numerals are used for corresponding details.

A particularity of the power supply device 1 according to the solution consists in that on the input side a network analysis device 15 is integrated, which performs a network analysis at the supply network applied on the input side at the input terminals 2-6 and determines one or more network parameters, namely the direction of rotation of the three-phase supply network at the input of the voltage converter and optionally in addition for example one or more of the following network parameters:
phase position of the supply network at the input of the voltage converter,
phase position at the output of the voltage converter,
voltages between the individual phases of the three-phase supply network at the input of the voltage converter,
voltages between the individual phases of the three-phase supply network and a neutral conductor at the input of the voltage converter,
insulation resistance of at least one phase of the supply network,
voltage type of the supply network for differentiating AC voltage and DC voltage,
frequency of the supply network.

Another particularity of the power supply device 1 consists in that a network analysis device 16 also is provided on the output side, which analyses the output network at the output terminals 7, 8 and determines at least one corresponding network parameter.

The two network analysis devices 15, 16 here are connected to the signaling device 10 which can output the network parameters via the communication interface 14.

In addition, the signaling device 10 here can link the network parameters measured by the network analysis devices 15, 16 and calculate an output quantity which is then output via the communication interface 14. For example, the efficiency of the power supply device 1 can thus be calculated, or the losses in the power supply device 1 can be determined.

The network parameter or the output quantity derived therefrom can, however, not only be output via the communication interface 14. In addition, the signaling device 10 also can correspondingly actuate the relay 11 in dependence on the network parameter. The signaling terminals 12, 13 can be parameterized arbitrarily by the network analysis device 15, 16 with individual or several quantities of the measurements.

Finally, the power supply device 1 includes an optical indication 17 that is connected to the signaling device 10 and provides for indicating the measured network parameters or quantities derived therefrom. The optical indication for example can be a light-emitting diode (LED) or a display (e.g. LCD display).

The network analysis device 15, 16 integrated into the power supply device I can measure current and/or voltage with a particular temporal resolution at particular time intervals, wherein corresponding measurement values of the current and/or the voltage are determined. In the present example, the time intervals are less than or equal to 6 ms, in particular less than or equal to 10 μs.

The network analysis device 15 is configured to monitor the relative phase position of the three phases of the supply network. Furthermore, the network analysis device 15 is configured to filter out high-frequency interferences, e.g. a surge pulse and/or a burst pulse.

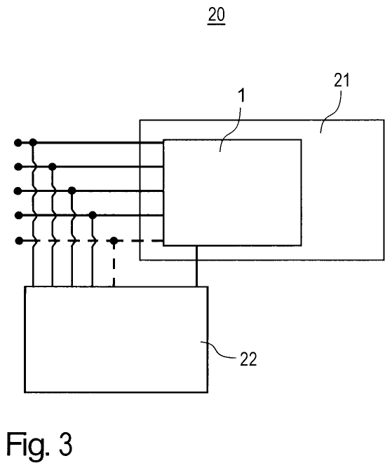

FIG. 3 shows a system 20 that comprises the power supply device 1 and a motor 22. The motor 22 is connected to the supply network in parallel to the power supply device 1, i.e. here to a three-phase network. The motor 22 receives a signal from the power supply device 1 via the communication interface 14 and/or the signaling terminals 12, 13, which signal indicates whether or not the correct (predetermined) direction of rotation of the three-phase supply network is applied at the input 2-6 of the voltage converter 9.

The power supply device 1 is arranged in a control cabinet 21.

According to an another example, there is proposed a power supply device for supplying at least one load from a supply network, which does not necessarily determine the direction of rotation of a three-phase supply network at the input of the voltage converter. This power supply device comprises a voltage converter 9 with an input 2-6 for connection to the supply network and an output 7, 8 for supplying the at least one load, a network analysis device 15, 16 for network analysis and for generating at least one network parameter, and a message output 12, 13, 14, wherein the network analysis device 15, 16 outputs the network parameter at the message output 12, 13, 14.

This voltage converter 9 can be a DC voltage converter, wherein the supply network is a DC network. Alternatively, the supply network can be a single-phase AC network or a three-phase AC network. Furthermore, the at least one network parameter can be the voltage type of the supply network for differentiating AC voltage and DC voltage.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

1 power supply device
2-6 input terminals
7,8 output terminals
9 switching power supply
10 signaling device
12, 13 signaling terminals
11 relay
14 communication interface
15 network analysis device at the input
16 network analysis device at the output
17 indication
20 system
21 control cabinet
22 motor

1. A power supply device for supplying at least one load from a three-phase supply network, comprising:
a) a voltage converter with an input for connection to the three-phase supply network and an output configured to supply the at least one load;
b) a network analysis device for network analysis and configured to generate at least one network parameter; and
c) a message output,
d) wherein the network analysis device is configured to output the at least one network parameter at the message output, and
e) wherein the at least one network parameter indicates a direction of rotation of the three-phase supply network at the input of the voltage converter.

2. The power supply device of claim 1, wherein at least one of
a) the network analysis device is configured to determine a further network parameter of the three-phase supply network at the input of the voltage converter, and
b) the network analysis device is configured to determine a further network parameter at the output of the voltage converter, the further network parameter comprising a utilization of the power supply device.

3. The power supply device of claim 1, wherein
a) the network analysis device is configured to measure at least one electrical quantity of the three-phase supply network at the input of the voltage converter,
b) the network analysis device is configured to measure at least one electrical quantity at the output of the voltage converter, and
c) the network analysis device is configured to link the quantity measured on the input side with the quantity measured on the output side to determine the network parameter, the network parameter comprising an efficiency of the power supply device or losses in the power supply device.

4. The power supply device of claim 1, wherein
a) the network analysis device is configured to measure at least one of current and voltage with a particular temporal resolution at particular time intervals and to determine corresponding measurement values of at least one of the current and/or the voltage, at time intervals of less than 50 ms, 20 ms, 10 ms, 5 ms or 1 ms, and
b) the network analysis device is configured to calculate the at least one network parameter from the measurement values.

5. The power supply device of claim 1, wherein the voltage converter comprises a power pack, comprising a switching power supply, and
wherein the three-phase supply network comprises an AC network.

6. The power supply device of claim 1, wherein a further network parameter is comprises at least one of:
a) phase position of the three-phase supply network at the input of the voltage converter,
b) phase position at the output of the voltage converter,
c) voltages between the individual phases of the three-phase supply network at the input of the voltage converter,
d) voltages between the individual phases of the three-phase supply network and a neutral conductor at the input of the voltage converter,
e) insulation resistance of at least one phase of the three-phase supply network,
f) frequency of the three-phase supply network.

7. The power supply device of claim 1, further comprising:
a switching output configured to output a switching signal in dependence on the at least one network parameter.

8. The power supply device of claim 1, further comprising:
an optical indication comprising a light-emitting diode, for status indication corresponding to the network parameter.

9. The power supply device of claim 1, further comprising:
a communication interface configured to control the power supply device from outside and/or to output the network parameter as a message output.

10. The power supply device of claim 1, wherein the voltage converter is configured to provide a safe DC voltage of 12 V, 24 V, or 48 V at the output.

11. A control cabinet, comprising:
the power supply device of claim 1.

12. A system, comprising:
the power supply device of claim 1.

13. The system of claim 12, further comprising:
a motor connected or connectable to the three-phase supply network.

14. The system of claim 13, wherein the motor is configured to start only when a predetermined direction of rotation is output at the message output.

15. The power supply device of claim 4, wherein the time intervals are 10 μs or less.

16. The power supply device of claim 7, wherein the switching signal is binary and assumes either a switch-on state or a switch-off state.
